(19) United States
(12) Patent Application Publication
(10) Pub. No.: US 2025/0164528 A1
(43) Pub. Date: May 22, 2025

(54) LIQUID-COOLED TERMINATION FOR RADIO FREQUENCY POWER MEASUREMENT

(71) Applicant: BIRD TECHNOLOGIES GROUP INC., Solon, OH (US)

(72) Inventors: Timothy HOLT, Chardon, OH (US); Joel MELTZER, Mentor, OH (US); John WINTER, Cuyahoga Falls, OH (US); Martin DUMMERMUTH, Chagrin Falls, OH (US)

(73) Assignee: BIRD TECHNOLOGIES GROUP INC., Solon, OH (US)

(21) Appl. No.: 18/836,196

(22) PCT Filed: Feb. 7, 2023
(86) PCT No.: PCT/US2023/012555

§ 371 Date: Aug. 6, 2024

Related U.S. Application Data
(60) Provisional application No. 63/307,172, filed on Feb. 7, 2022.

(51) Int. Cl. G01R 15/00; G01R 21/02; H01P 1/30

(52) U.S. Cl. CPC G01R 15/00; G01R 21/02; H01P 1/30

(57) ABSTRACT

Disclosed is a liquid-cooled termination for calorimic RF power measurement having an RF transmission line, a coolant flowpath having a coolant input and a coolant output, and an RF load. The RF transmission line being electrical communication with said RF load having a resistor and a heat sink. The RF load is in the coolant flowpath, such that said heat generated by the RF power being applied to the RF load through said RF transmission line is convected to the coolant while said coolant flows past said RF load.

### CROSS-REFERENCE TO RELATED APPLICATIONS

This application claims priority to U.S. Provisional Patent Application Ser. No. 63/307,172, filed Feb. 7, 2022, and titled LIQUID-COOLED LOAD FOR POWER MEASUREMENT, which is herein incorporated by reference in its entirety.

### FIELD OF THE INVENTION

This application is directed to radio frequency (RF) power measurement. More specifically, to a RF power measurement using a calorimeter having a liquid-cooled termination.

### BACKGROUND OF THE INVENTION

The RF calorimeter has long been considered the most accurate method for the measurement of RF power. National Institute of Standards (NIST) maintains transfer references for a standard watt of RF power in the form of various absolute-flow microwave calorimeters for different frequency bands.

### BRIEF SUMMARY OF THE INVENTION

According to one aspect of the present invention, a liquid-cooled termination for calorimic RF power measurement is provided having an RF transmission line, a coolant flowpath having a coolant input and a coolant output, and an RF load. The RF transmission line being electrical communication with said RF load having a resistor and a heat sink. The RF load is in the coolant flowpath, such that said heat generated by the RF power being applied to the RF load through said RF transmission line is convected to the coolant while said coolant flows past said RF load.

Advantages of the present invention will become more apparent to those skilled in the art from the following description of the embodiments of the invention which have been shown and described by way of illustration. As will be realized, the invention is capable of other and different embodiments, and its details are capable of modification in various respects.

### BRIEF DESCRIPTION OF SEVERAL VIEWS OF THE DRAWINGS

These and other features of the present invention, and their advantages, are illustrated specifically in embodiments of the invention now to be described, by way of example, with reference to the accompanying diagrammatic drawings, in which:

FIGS. 1A-C depict a liquid-cooled termination for RF power measurement in accordance with an embodiment of the various disclosed aspects herein;

FIGS. 2A-J depict a liquid-cooled termination for RF power measurement in accordance with a further embodiment of the various disclosed aspects herein;

FIGS. 3A-M depict a liquid-cooled termination for RF power measurement in accordance with a further embodiment of the various disclosed aspects herein;

FIG. 4 depicts a calorimeter having a liquid-cooled termination for RF power measurement in accordance with the embodiments of the various disclosed aspects herein.

FIGS. 5A-B are thermal images of a liquid-cooled termination for RF power measurement being used with a calorimeter in accordance with the embodiments of the various disclosed aspects herein.

FIGS. 6A-E depict a liquid-cooled termination for RF power measurement in accordance with a further embodiment of the various disclosed aspects herein; and

FIGS. 7A-G depict a liquid-cooled termination for RF power measurement in accordance with a further embodiment of the various disclosed aspects herein.

It should be noted that all the drawings are diagrammatic and not drawn to scale. Relative dimensions and proportions of parts of these figures have been shown exaggerated or reduced in size for the sake of clarity and convenience in the drawings. The same reference numbers are generally used to refer to corresponding or similar features in the different embodiments. Accordingly, the drawing(s) and description are to be regarded as illustrative in nature and not as restrictive.

### DETAILED DESCRIPTION OF THE PREFERRED EMBODIMENT

Approximating language, as used herein throughout the specification and claims, may be applied to modify any quantitative representation that could permissibly vary without resulting in a change in the basic function to which it is related. Accordingly, a value modified by a term or terms, such as “about”, is not limited to the precise value specified. In at least some instances, the approximating language may correspond to the precision of an instrument for measuring the value. Range limitations may be combined and/or interchanged, and such ranges are identified and include all the sub-ranges stated herein unless context or language indicates otherwise. Other than in the operating examples or where otherwise indicated, all numbers or expressions referring to quantities of ingredients, reaction conditions and the like, used in the specification and the claims, are to be understood as modified in all instances by the term “about”.

“Optional” or “optionally” means that the subsequently described event or circumstance may or may not occur, or that the subsequently identified material may or may not be present, and that the description includes instances where the event or circumstance occurs or where the material is present, and instances where the event or circumstance does not occur or the material is not present.

As used herein, the terms “comprises”, “comprising”, “includes”, “including”, “has”, “having”, or any other variation thereof, are intended to cover a non-exclusive inclusion. For example, a process, method, article or apparatus that comprises a list of elements is not necessarily limited to only those elements, but may include other elements not expressly listed or inherent to such process, method, article, or apparatus.

In addition, the language used in the specification has been principally selected for readability and instructional purposes, and may not have been selected to delineate or circumscribe the inventive subject matter. Accordingly, the disclosure of the embodiments is intended to be illustrative, but not limiting, of the scope of the embodiments, which is set forth in the claims.

As was stated above, the RF calorimeter has long been considered the most accurate method for the measurement of RF power. The term calorimetry refers to the measurement of quantities of heat. The principle is based on the first law of thermodynamics which states that energy cannot be created or destroyed, only converted from one form to another. Heat is energy that can be transferred by a thermal process which can be expressed as a change in energy per unit time. The principle of RF calorimetry assumes complete conversion of RF energy into thermal energy by a resistive device. The heat generated by the resistive device results in a temperature rise in the device and its surroundings. If the surroundings include a moving, liquid coolant, then the power dissipated in load can be determined by measuring the difference in inlet and outlet liquid temperature (ΔT) the flow rate (f) of the coolant and specific heat of the coolant (Cp). The power applied can be determined by P (watts)=Cp*f*ΔT.

Most calorimetric radio frequency power measurement systems depend upon the use of liquid cooled radio frequency terminations. These devices serve two purposes within the calorimeter system. The first purpose of the termination is to provide a transmission line termination load that remains at or near the transmission line characteristic impedance across the operating frequency of the calorimeter system. The second purpose of the termination is to convert the radio frequency energy into heat, which provides for a first principles means of determining the energy within the applied radio frequency waveform. It is important that this termination provide high thermal efficiency, thus capturing as much of the converted energy as possible. As the requirement for better radio frequency power measurement accuracy have increased, the requirement for more efficient terminations has followed. This invention describes a new family of liquid cooled radio frequency terminations, with good performance in terms of electrical characteristics, as well as superior thermal performance as compared to currently available liquid cooled terminations. It addresses the problem of a manufacturable, liquid-cooled radio frequency (RF) dummy load that when included in an absolute flow calorimeter system is capable of accurate, high-power RF power measurement. The embodiment of this invention minimizes parasitic heat losses such that close to 100% of the RF power is converted to heat and this energy is wholly transferred to the coolant enabling truer measurement of coolant temperature rise.

The resistive device commonly used in high-power RF termination is a coaxial, liquid-cooled dummy load such as is disclosed by Lesik U.S. Pat. No. 3,906,402. This liquid-cooled radio frequency termination uses a thick film, or thin film tubular resistors with resistive films applied to outside surfaces of ceramic substrates. Coolant paths for the purpose of removing heat generated by the resistive films bring the coolant in close proximity to the resistive film. In some configurations, the coolant path is contained within the inside of the ceramic substrate, whereas in other configurations coolant is routed such that it is in direct contact with the resistive film. Highly accurate temperature sensors are placed on the fluid inlet and outlet to measure the temperature difference between the incoming and outgoing cooling fluid presented to the load. The main issue with these liquid cooled termination configurations is that there are significant thermal paths from the internal resistor assembly, to the body of the termination. These thermal paths result in lost energy that is not captured within the termination coolant path. When these terminations are use in calorimetric power measurement applications, any thermal energy that is not contained within the coolant path will manifest itself as a potential error in power measurement. In addition, the magnitude of these errors is variable, dependent upon the temperature gradient that exists between the termination body, and the external environment.

Meltzer, et. al., U.S. Pat. No. 10,168,365, discloses a microfabricated approach to RF power measurement using a planar structure. Meltzer uses a planar load, fluid channels and temperature sensors fabricated on a common substrate. The main limitation to Meltzer is the maximum power that can be absorbed.

Accurate flow calorimeter power measurement assumes 100% of the incident power is converted to heat and this heat is completely transferred to the coolant. The embodiment of this invention minimizes parasitic heat losses through novel placement of the conductive, resistive and insulating materials such that close to 100% of the RF power is converted to heat and this energy is wholly transferred to the coolant enabling truer measurement of coolant temperature rise.

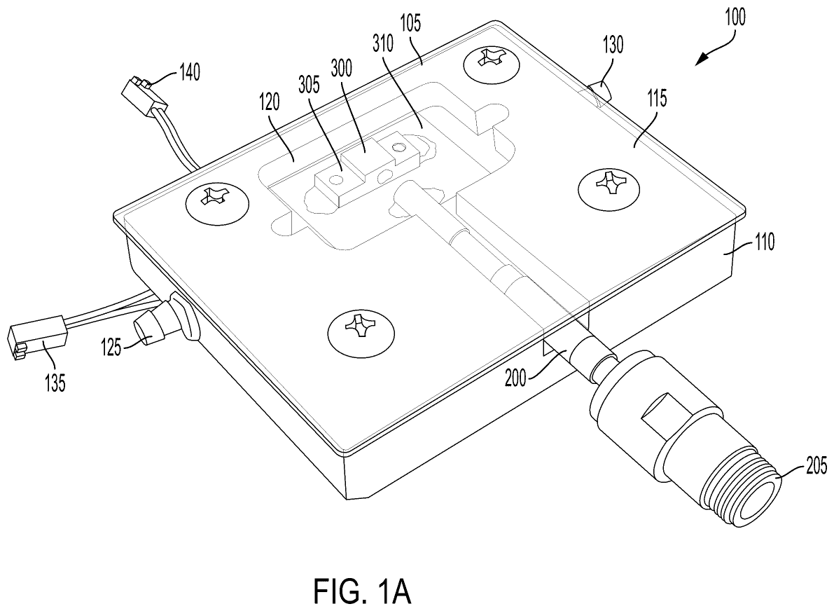

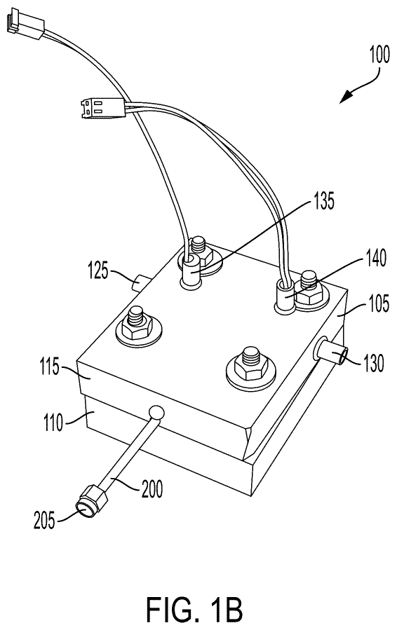

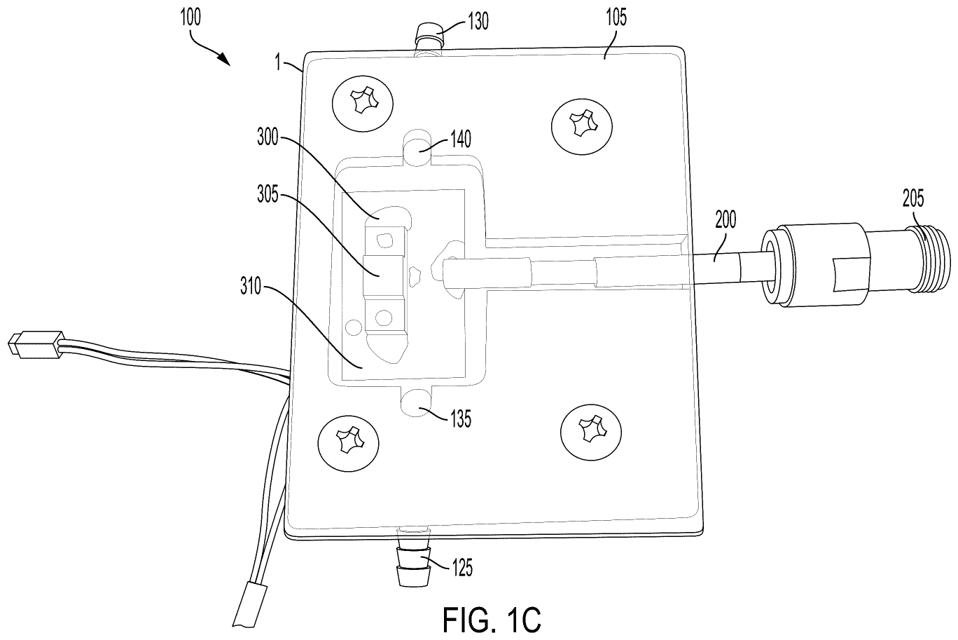

A first embodiment of a liquid-cooled termination 100 for RF power measurement is illustrated in FIGS. 1A-C. The termination 100 has a case 105 comprised of a base 110 and a lid 115 with a coolant chamber 120. In some embodiments, the case 105 is rectangular. In other embodiments, case 105 can be other shapes. The coolant chamber 120 is sealed by lid 115. The material of case 105 is constructed of material with low thermal conductivity. The case 105 also has a coolant inlet 125 and a coolant outlet 130 that permits coolant to enter and exit the coolant chamber 120 of the case 105. A temperature of the coolant entering the coolant chamber 120 is measured by inlet coolant temperature sensor 135 and the temperature of the coolant exiting the cavity is measured by outlet coolant temperature sensor 140. O-rings can be used at the interfaces between components of the liquid-cooled termination 100 to keep the fluid from escaping the fluid flow path of liquid-cooled termination 100, which includes the coolant inlet 125, coolant chamber 120, and coolant outlet 130. For example, an O-ring may be present between the base 110 and lid 115. Further an O-ring may be placed around the exterior 216 of transmission line 200 to keep fluid from leaking around the exterior 216 of transmission line 200 where the transmission line 200 enters case 105.

In some embodiments, the RF power to be measured is introduced to the liquid-cooled termination 100 through transmission line 200 which has an input connector 205 on a first end 206 and electrically connects to the RF load 300 on a second end 207 opposite the input connector 205. Input connector 205 can be a standard coaxial interface, such as a type N or SMA. In some embodiments, transmission line 200 can have an RF transition 210 at the second end that electrically connects the transmission line 200 to the RF load 300. Transmission line 200 has an outer conductor 215 comprising a tube made of a low electrically and thermally conductive material, such as glass, quartz, or other ceramic material. An exterior 216 of the outer conductor 215 is coated with a highly electrically conductive material, such as silver, gold, or copper. An inner conductor 220 is coaxially located inside for the outer conductor 215. The inner conductor 220 can be an ultra-thin wall tube constructed of a highly electrically conductive material, or constructed of a low electrically conductive material that is coated with a high electrically conductive material on the exterior. In some embodiments, the wall thickness of the inner conductor 220 can be between about 0.005″-0.060″.

Insulation 225 is concentrically placed between the outer conductor 215 and inner conductor 220. The Insulation 225 can also be in the shape of a tube and is comprised of a low-dielectric material. Insulation 225 supports the inner conductor 220 to maintain concentricity with the outer conductor 215. The wall thickness of the outer conductor 215, as well as the insulation 225, and inner conductor 220 are chosen such that the characteristic impedance of the transmission line 200 is as close to 50 ohms as possible. In an embodiment, the gap/space between the inner conductor 220 and the outer conductor 215 can be between about 0.010″-0.060″. The input connector 205 is electrically connected to the outer conductor 215 and inner conductor 220. The outer conductor 215 and inner conductor 220 are electrically connected to the RF load 300. In an embodiment, the outer conductor 215 and inner conductor 220 can be electrically connected to the RF load 300 through the RF transition 210.

The RF load 300 can be a planar load comprised of a resistor 305 that can be a thick film resistor. In some embodiments, the RF load 300 can be shaped to match the desired load impedance. The RF load 300 can also have a heat sink and/or heat-spreader 320 attached to the resistor 305 for convecting the heat generated by the resistor 305.

The construction of the transmission line 200 minimizes conductive heat loss from the RF load 300 due to the extremely small cross-section of the thin-walled inner conductor 220 and the thermally insulative properties of the outer conductor 215. This minimal conductive heal loss through the transmission line 200 differentiates over prior art designs, which were less accurate due to high heat loss through the transmission line 200.

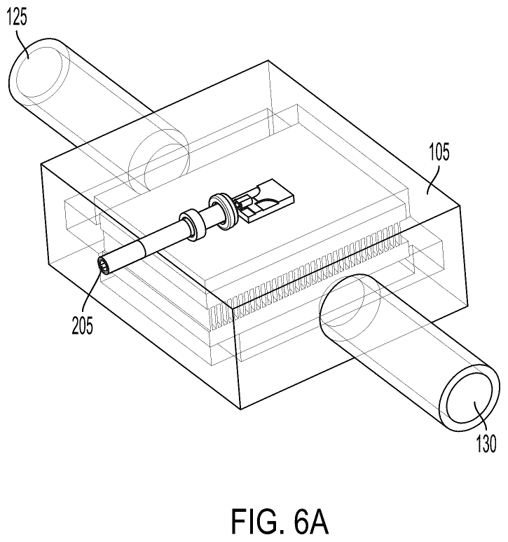

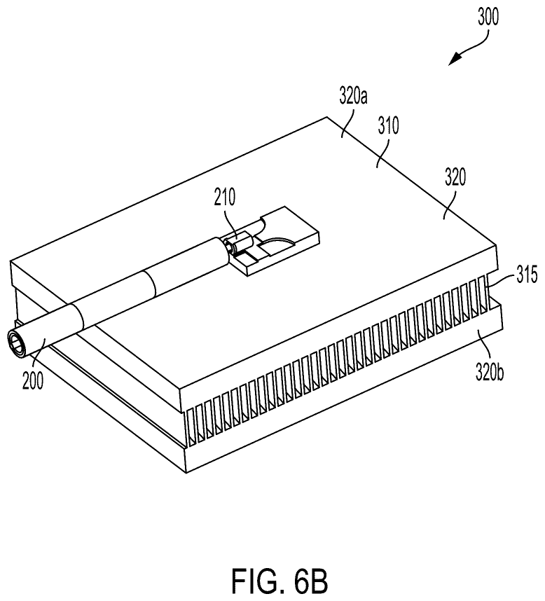

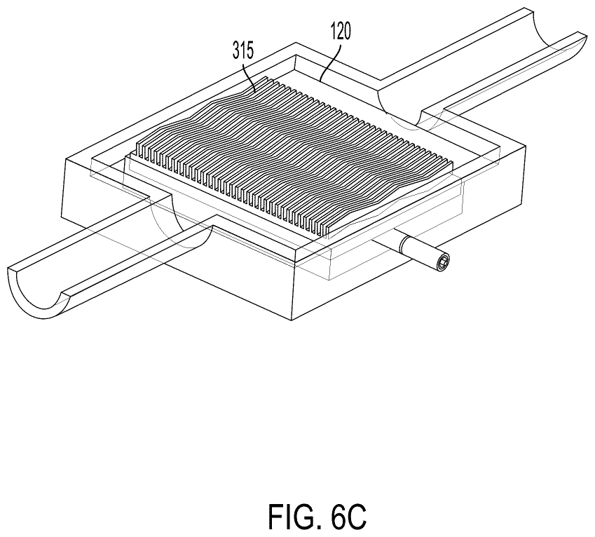

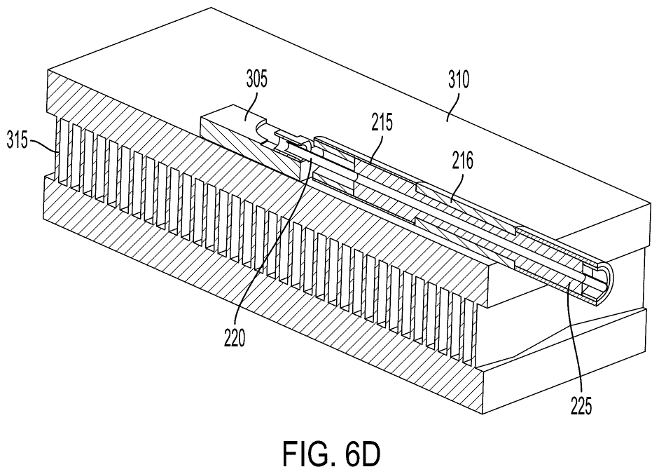

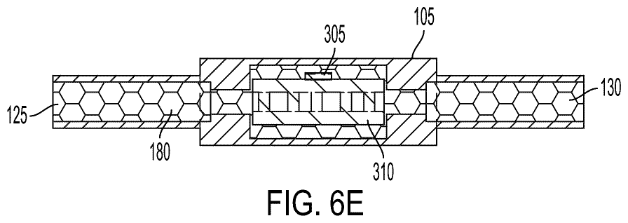

Another embodiment of liquid-cooled termination 100 is shown in FIGS. 6A-E and is also described, in conjunction with FIGS. 1A-C. Upon review of the figures, it can be seen that the inlet coolant temperature sensor 135 and outlet coolant temperature sensor 140 can be externally located or integrated into the case 105. Further, in some embodiments, inlet coolant temperature sensor 135 and outlet coolant temperature sensor 140 can be thermocouple or resistance temperature detector (RTD). Further, upon review of FIG. 6A-E, it can be seen that heatsink 310 of RF load 300 can take on a variety of forms. For example, the fins 315 of heatsink 310 can have a folded-fin topology such that the coolant progresses both through the fins 315 and over the base. The heatsink 310 can be constructed of a thin herringbone folded fin structure with a heat-spreader 320 soldered to both sides of the fins 315 parallel to the coolant flow path, such that an upper heat-spreader 320a is located on the top of the fins 315 and a lower heat-spreader 320b is located under the fins. Coolant progresses through the fins 315 and over both sides of the heat-spreader 320, namely the upper heat-spreader 320a and lower heat-spreader 320b. In some embodiments, the folded fins 315 can be arranged in straight pattern. In other embodiments, the folded fins 315 can be arranged in herringbone pattern, such as is depicted in 6C, which helps to maximize heat transfer from the heatsink 310 to the coolant by increasing the surface area of the fins 315 and maximizing turbulence in the coolant passing through heatsink 310.

Further, the coolant chamber 120 can be sized to minimize the space between the walls 121 of the coolant chamber 120 and the RF load 300, which helps to maximize the contact of the coolant with the RF load 300, thereby maximizing heat transfer from the RF load 300 to the coolant 180 and helping to ensure uniform heating of the coolant flowing through coolant chamber 120. Further, the coolant inlet 125 and coolant outlet 130 can be positioned such that the fins 315 are parallel to the coolant flow path.

Turning to the RF load 300, in some embodiments, RF load 300 is a planar load structure that has include a microstrip topology. To form RF load 300 as a planar load, the resistor 305 is formed by placing a planar dielectric material between a conductive or resistive strip and a continuous ground plane. It has a substrate of thermally conductive but electrically insulative material, typically a ceramic. This substrate can be die-cut into a square or rectangular shape. On the top surface of the substrate, a resistive film 306 is printed or patterned. The shape and size of this top pattern are chosen to match the characteristic impedance to the connected transmission line and to maximize the return loss and are directly influenced by the dielectric constant and thickness of the substrate.

A protective, encapsulating coating is applied over the surface to protect the film 306 from chemical or mechanical degradation. To enable continuity to ground, a conductive wrapping is applied on one end which wraps around one side of the substrate. A small conductive ‘patch’ is placed in the opposite end where the RF energy is introduced. The bottom of the substrate is bonded to a heat-spreader 320 which provides ground continuity and also mounts the substrate to the heat-spreader 320.

It is contemplated that some embodiments of the liquid-cooled termination 100 may use resistors 305 and/or heat-spreaders 320 having a low thermal mass to allow for fast transient response and therefore fast stabilization file of the coolant temperature.

Thus, as can be seen in FIG. 6B, the shape of the film 306 of resistor 305 can be shaped to match the desired load impedance. Further, the shunt 307 of resistor 305 can be shaped to tune the resistor 305 for optimal match of the desired load. Additionally, resistor 305 can be comprised of resistors 305 cascaded in series or in parallel and connected with one or more jumpers. The one or more upstream resistors 305 would act as an attenuator and the resistor 305 most downstream would act as a termination to take up the residual power. Cascading multiple resistors permits for dissipating the RF energy over a larger surface area. Further, resistor 305 can be placed on either the top or bottom of heatsink 310. Further, it is contemplated that the coolant is a coolant other than water. In some embodiments, coolant is a non-conductive fluid, such as silicon oil. Additionally, it is contemplated that in some embodiments, a turbulent mixer 150 is present at the coolant outlet 130 to reduce heat stratification in the coolant exiting the liquid-cooled termination.

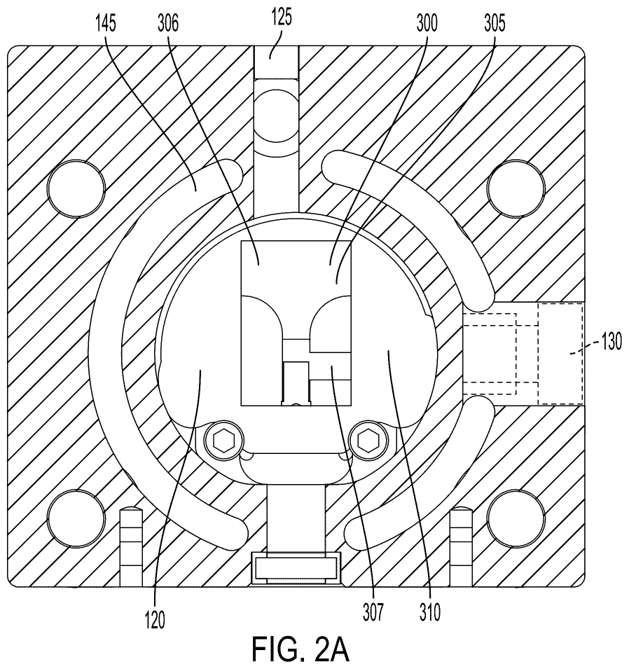

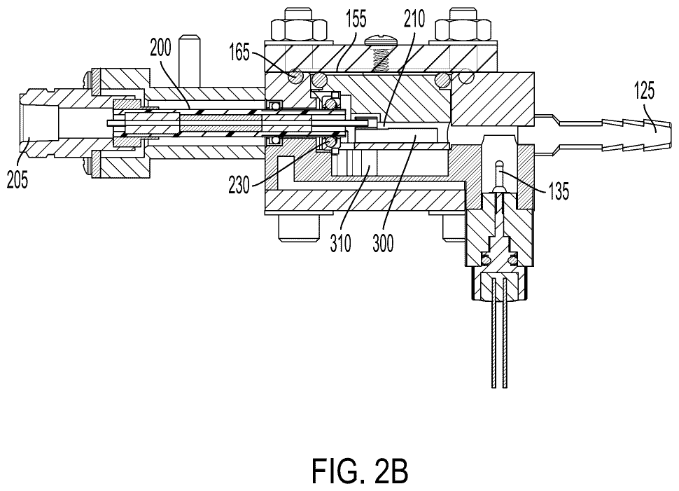

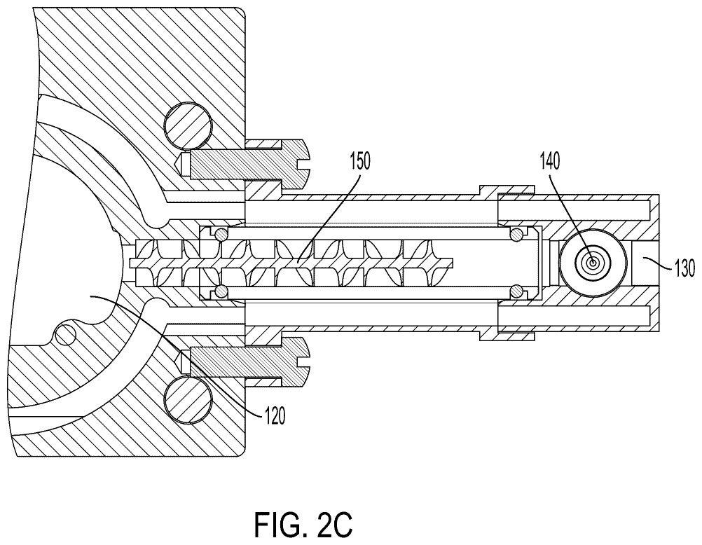

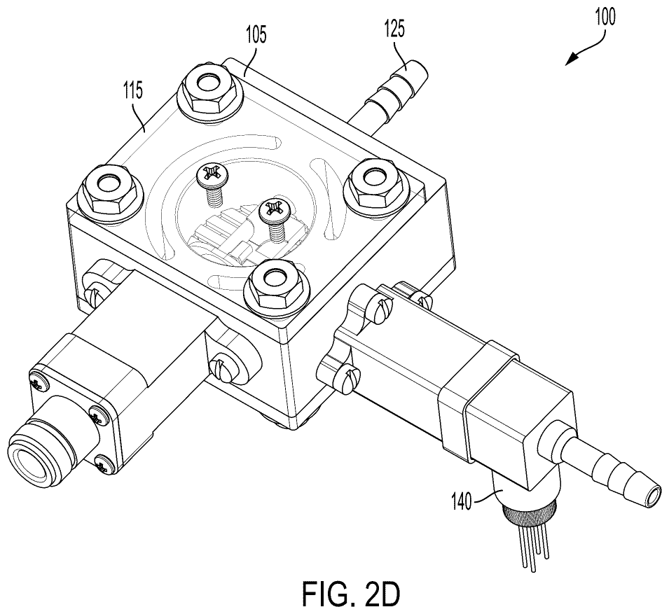

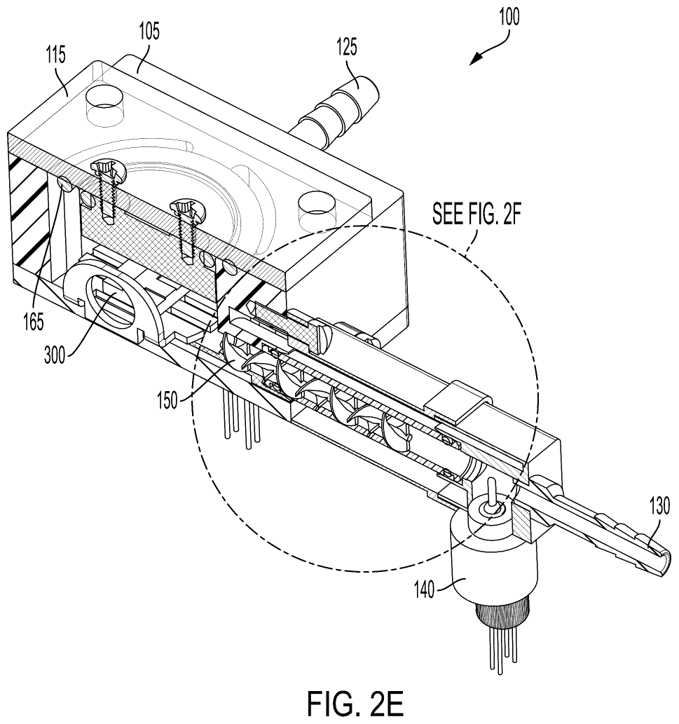

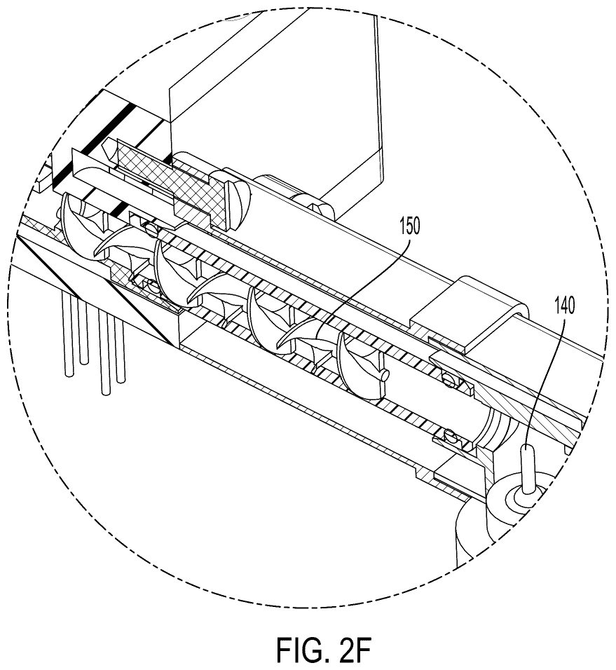

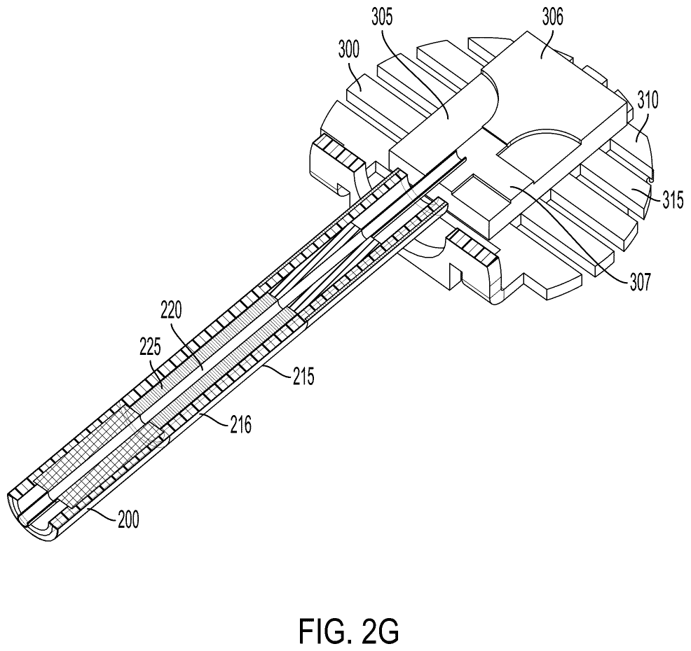

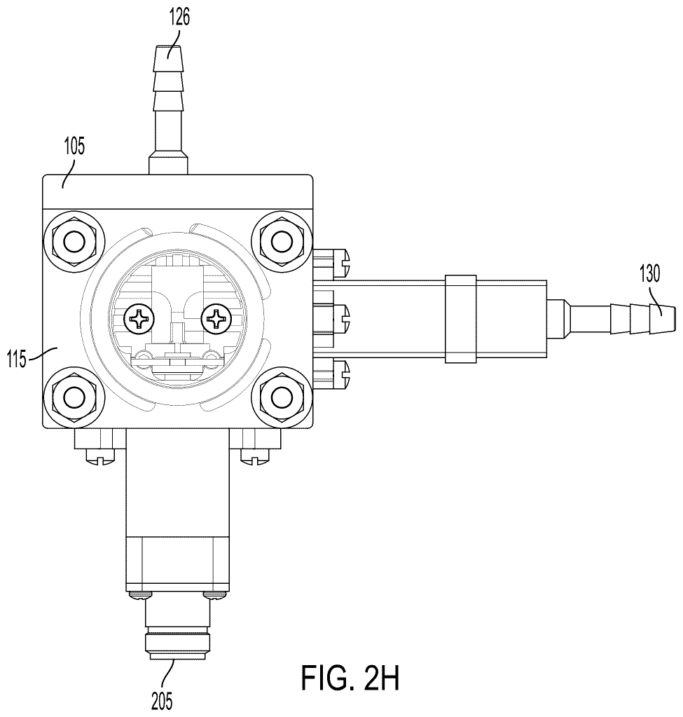

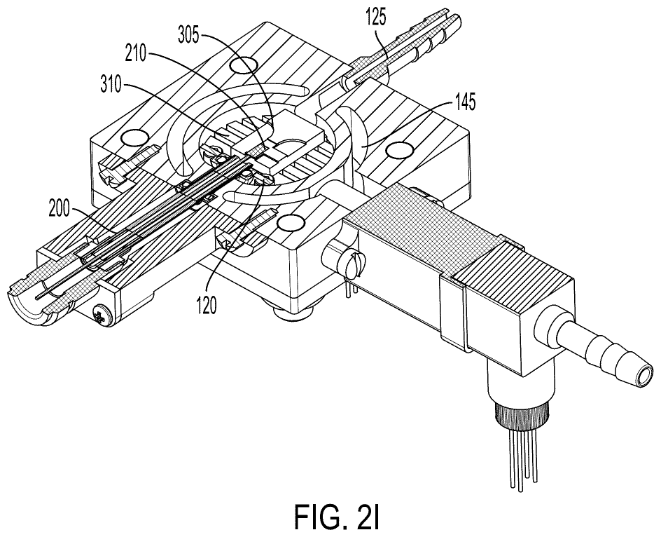

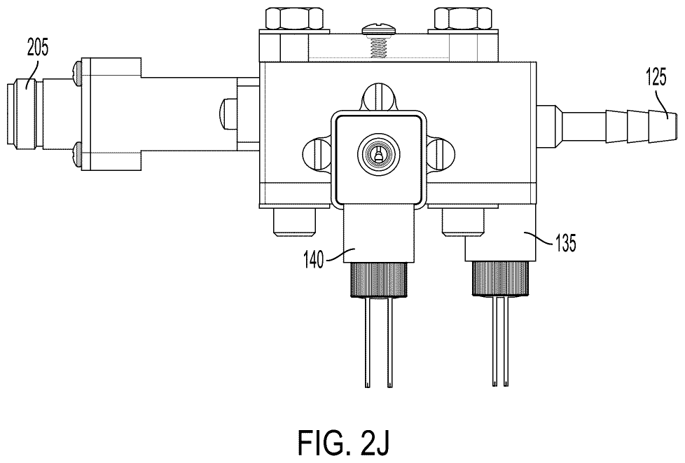

Turning to FIGS. 2A-2J in conjunction with FIGS. 1A-C and FIGS. 6A-E, FIGS. 2A-2J are directed to another embodiment of liquid-cooled termination 100. As can be seen in this embodiment, coolant chamber 120 is thermally isolated from the case 105 by minimizing material connected to coolant chamber 120 and placing an insulative boundary 145 around the perimeter of the coolant chamber 120, thereby creating insulation between coolant chamber 120 and the case 105, which decreases the transfer of heat from the coolant within coolant chamber 120 to the case 105. In some embodiments, the insulation of the insulative boundary 145 can be air, although it is contemplated that other insulating materials may be used in place or, or in conjunction with, air.

Further, a turbulent mixer 150 is present in the coolant flowpath between the RF load 300 and before the coolant outlet 130. In this embodiment, the outlet coolant temperature sensor 140 is located between the turbulent mixer 150 and the coolant outlet 130. Additionally, in this embodiment, the coolant inlet 125 and coolant outlet 130 are oriented perpendicular to each other, causing additional turbulance in the coolant along the flowpath. In other embodiments, of the liquid-cooled termination 100, such as those shown in FIGS. 1A-C and FIGS. 6A-E, the coolant inlet 125 and coolant outlet 130 are in-line with each other. Further, a diverter 155 is present at the top 122 of the coolant chamber, which creates a consistent ceiling height 161 along the coolant flow path 160, such as when coolant travels from the coolant inlet 125 through the coolant chamber 120 and out the coolant outlet 130. The diverter 155 also provides some insulation between the coolant in the coolant chamber 120 and the lid 115 of case 105.

Further, an RF gasket 230 is present that electrically connects the outer conductor 215 with the heatsink 310 of RF load 300. The inner conductor 220 is electrically connected to the resistor 305 of RF load 300 through an RF transition 210. In other embodiments, it is contemplated that inner conductor 220 may be electrically connected to the resistor 305 of RF load 300 using solder. In other embodiments, it is contemplated that inner conductor 220 may be electrically connected to the resistor 305 of RF load 300 through a socket that is soldered to resistor 305. Resistor 305 is electrically and mechanically connected to heatsink 310 of RF load 300. The inner conductor 220 and outer conductor 215 are electrically connected to input connector 205.

As can be seen, in practice liquid-cooled termination 100, as shown in FIGS. 1A-C and FIGS. 6A-E, the resistor 305 and heatsink 310 of RF load 300 load are immersed in coolant within the coolant chamber 120. Coolant enters coolant chamber 120 through the coolant inlet 125 and the coolant temperature is monitored by a inlet coolant temperature sensor 135 in the path of the coolant either before entering the coolant inlet 125 or upon exiting the coolant inlet 125. The reading of the input coolant temperature is passed by the inlet coolant temperature sensor 135 to an external device, such as a microcontroller, via sensor leads.

In the coolant chamber 120, the fluid travels over the resistor 305 and heatsink 310 of the RF load 300. Here the RF energy provided to the input connector 205 of transmission line 200 has been converted to heat via the resistive loss of the film 306 of resistor 305. The RF load 300 is positioned such that the film 306, heat-spreader 320, and fins 315 are in a direct path of the coolant as it enters the coolant chamber 120. Heat flow that is conducted through the RF load 300, such as through the film 306, heat-spreader 320, and fins 315 are directly convected to the coolant. As can be seen, the RF energy converted to heat will be almost completely transferred to the coolant by forced-convection.

The heated coolant exits the coolant chamber 120 through the coolant outlet 130 and may traverse through a turbulent mixer 150 after passing through the coolant outlet 130. The turbulent mixer 150 device introduces further turbulence in the fluid. The temperature of the coolant exiting the turbulent mixer 150 is then measured using an outlet coolant temperature sensor 140 and passed by the outlet coolant temperature sensor 140 to an external device, such as a microcontroller, via sensor leads.

If a turbulent mixer 150 is not present the temperature of the coolant can be read by the outlet coolant temperature sensor 140 prior to or after the coolant exits the coolant outlet 130, and passed by the outlet coolant temperature sensor 140 to an external device, such as a microcontroller, via sensor leads.

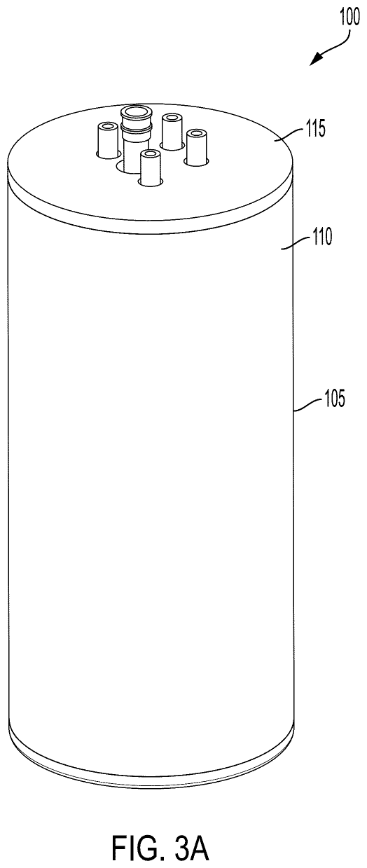

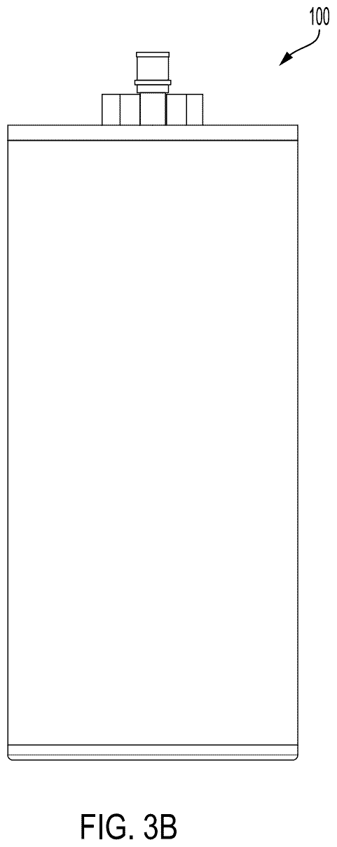

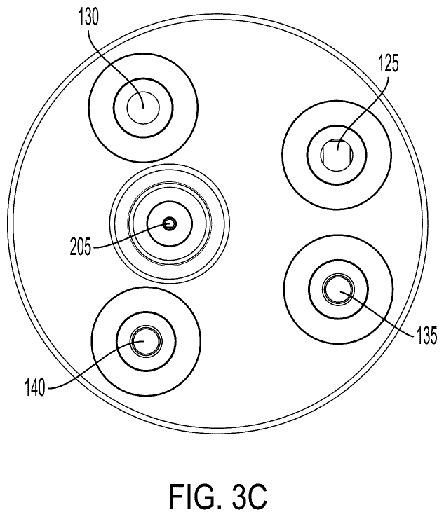

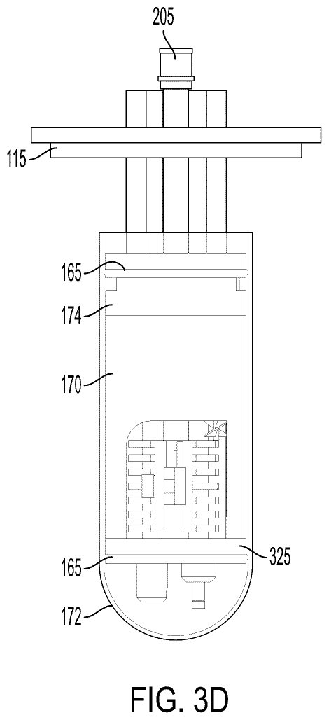

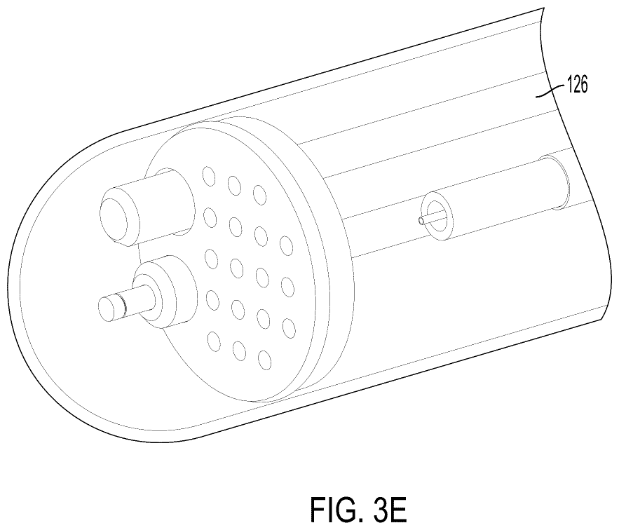

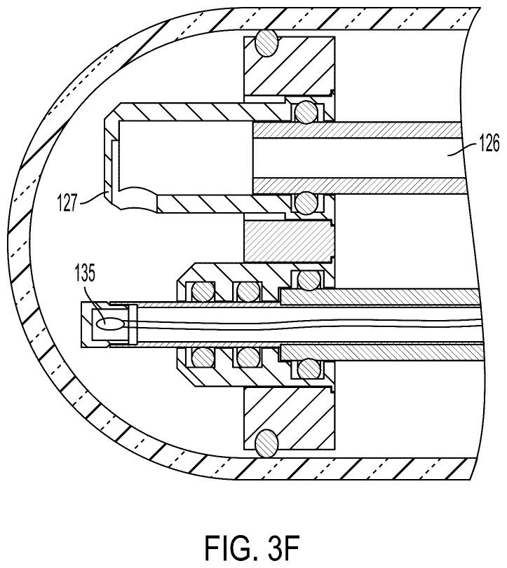

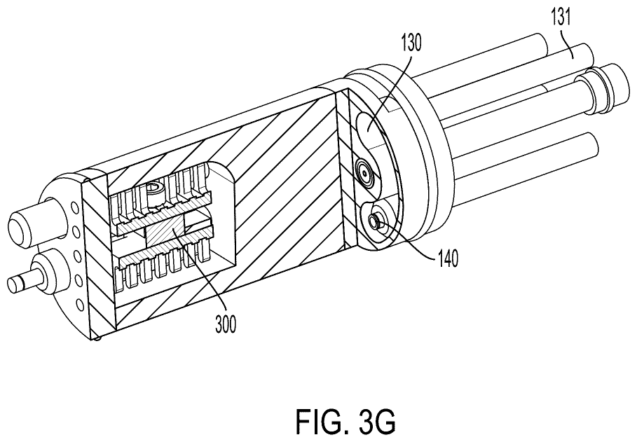

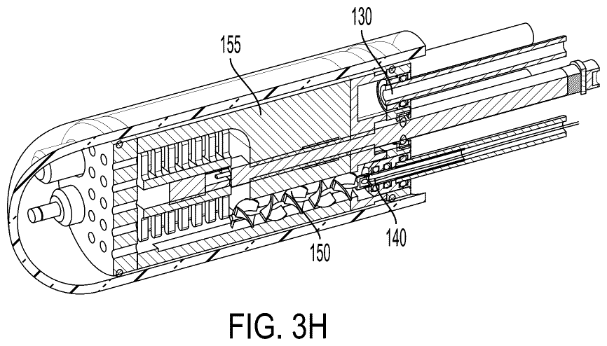

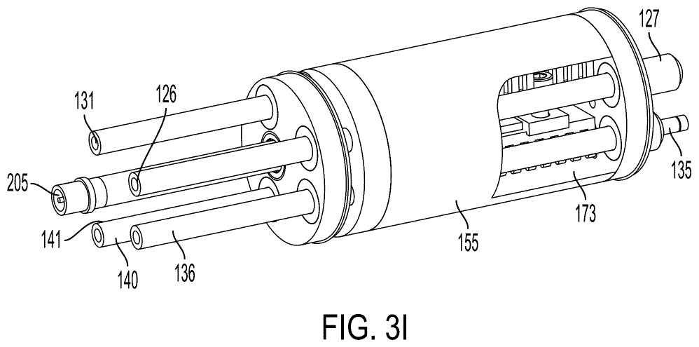

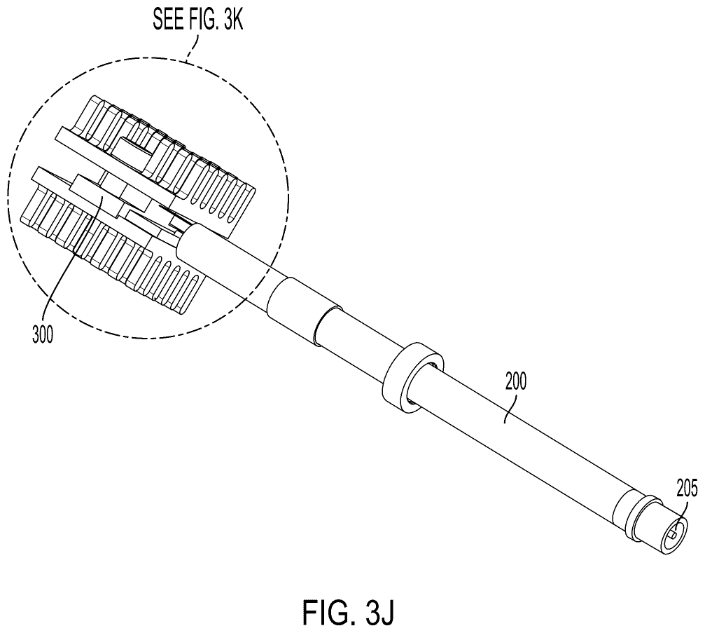

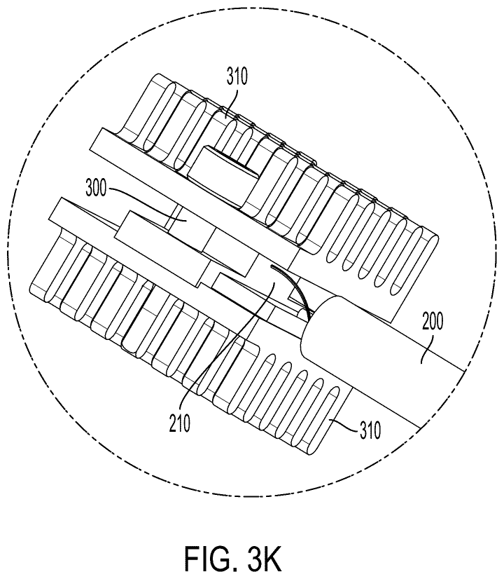

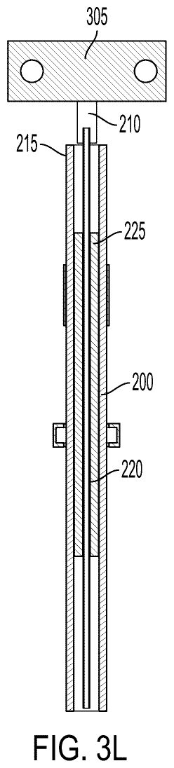

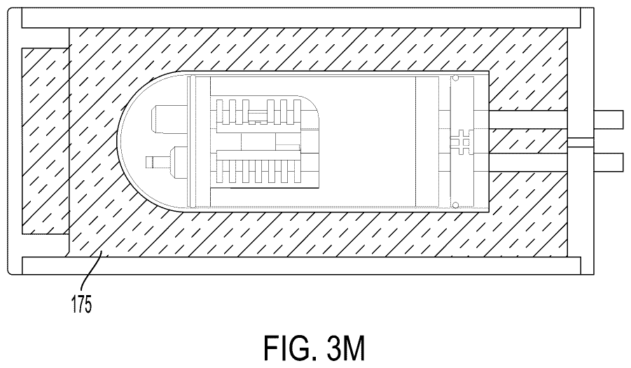

Further, FIGS. 3A-3L depict another embodiment of liquid-cooled termination 100. In this embodiment, case 105 is cylindrical shaped made of a material with low thermal conductivity. Case 105 has a base 110 and lid 115. Coolant inlet 125, coolant outlet 130, inlet coolant temperature sensor 135, outlet coolant temperature sensor 140 and input connector 205 of transmission line 200 all present on lid 115. RF is introduced through input connector 205. Coolant flows into liquid-cooled termination 100 through coolant inlet 125 and exits through coolant outlet 130. It is contemplated that in this embodiment, coolant inlet 125 and coolant outlet 130 are constructed of a low thermal conductivity material, such as quartz, or another material with similar thermal properties as the outer conductor 215, to minimize conductive heat loss to the case 105. Inlet coolant temperature sensor 135 and outlet coolant temperature sensor 140 measure the temperature of the coolant inside liquid-cooled termination 100.

In this embodiment of liquid-cooled termination 100, the coolant is contained in a glass tube with and rounded bottom and an open end that is sealed with an inner fluid chamber seal 174 using an O-ring 165.

RF power introduced through input connector 205 travels down inner conductor 220 of transmission line 200 and passes through RF transition 210 to resistor 305 of RF load 300. Resistor 305 is electrically and mechanically attached to at least one heatsink 310. The RF load 300, namely the resistor 305 and the at least one heatsink 310, rest on the top of a diffuser 325. This configuration allows the RF load 300 to “float” in the coolant with minimal contact with the remaining structures. The RF power then passes to the heat sink(s) and back to the input connector 205 through the outer conductor 215.

The resistor 305 and heatsink(s) 310 are immersed in the coolant contained by an inner fluid chamber 170. In an embodiment, the inner fluid chamber 170 can be constructed from a large, thin, glass vessel having a “test tube” form-factor. The inner fluid chamber 170 is thermally isolated from the case 105 through insulation 175 placed between the inner fluid chamber 170 and the case 105. Insulation 175 may be closed cell foam, or another suitable insulation material.

In practice, coolant enters the liquid-cooled termination 100 through coolant inlet 125. Coolant inlet 125 has a coolant inlet pipe 126 which conveys the coolant toward the bottom 171 of the inner fluid chamber 170. The coolant inlet 125 and pipe 126 are constructed of a low thermal conductivity material, such as quartz, or another material with similar thermal properties as the outer conductor 215, to minimize conductive heat loss to the case 105. Coolant travels to the bottom 171 of the inner fluid chamber 170 and enters a small mixing chamber 172 formed by the bottom 171 of the inner fluid chamber 170 and the diffuser 325 with O-ring 165. The coolant exits the coolant inlet pipe 126 through an orifice 127 located at the exit 128 of the coolant inlet pipe 126. The orifice 127 is located at a 90 degree angle with respect to the longitudinal axis of the coolant inlet pipe 126. The 90 degree angle of the orifice 127 provides initial mixing and temperature stabilization of the coolant. The orifice 127 projects the coolant at the inlet coolant temperature sensor 135, such that the inlet coolant temperature sensor 135 is in the path of the coolant exiting orifice 127. The inlet coolant temperature sensor 135 has a coolant temperature sensor inlet pipe 136 through which the inlet coolant temperature sensor 135 and associated wires passes through the lid 115 of case 105.

The coolant temperature sensor inlet pipe 136 and coolant temperature sensor outlet pipe 141 are constructed of a low thermal conductivity material, such as quartz, or another material with similar thermal properties as the outer conductor 215, to minimize conductive heat loss to the case 105. A distal end 137 of the coolant temperature sensor inlet pipe 136 has a conductive portion where inlet coolant temperature sensor 135 is located. In other embodiments, the conductive portion is not present at the distal end 137 and instead the inlet coolant temperature sensor 135 is attached to the exterior of the distal end 137. In some embodiments, an intermediate pipe 138 is present between the upper portion 139 of the coolant temperature sensor outlet pipe 141 and the distal end 137. In embodiments where the intermediate pipe 138 is present, the intermediate pipe 138 does not extend beyond the diffuser 325. The intermediate pipe 138 can be formed of any non-conductive material.

The coolant temperature is measured by the inlet coolant temperature sensor 135 immediately before the coolant exits the small mixing chamber 172 by passing through the diffuser 325 to enter the load chamber 173. The measurement of the coolant temperature by the inlet coolant temperature sensor 135 is passed by the inlet coolant temperature sensor 135 to an external device, such as a microcontroller, via sensor leads extending from the coolant temperature sensor inlet pipe 136.

The measurement of the coolant temperature occurs immediately before the coolant exits the small mixing chamber 172, which ensures any heat that may conduct internally to the incoming coolant is properly measured to accurately determine the true temperature rise in the coolant. The load chamber 173 is located above the small mixing chamber, closer to the lid 115 of the case 105. The load chamber 173 formed by the diffuser 325 and diverter 155.

In an embodiment, the diffuser 325 has apertures 326 that are oriented parallel to the inner fluid chamber 170 and perpendicular to the direction of the coolant exiting orifice 127. The diffuser 325 provides for even distribution of coolant across the RF load 300. In other embodiments, the diffuser 325 can direct a higher flowrate of coolant to areas of the RF load 300 that require higher convention coefficients and vice-versa. When the coolant enters the load chamber 173 through diffuser 325, the coolant passes over the resistor 305 and heatsink 310 of RF load 300. The coolant is heated up by the resistor 305 and heatsink(s) 310 of RF load 300 when RF energy is applied to the load 300. The RF load 300 converts the RF energy to heat, which is then convected to the coolant (transferred to the coolant using convective heat transfer). In this embodiment, the resistor 305 and heatsink(s) 310 of the RF load 300 are positioned in the direct path of the coolant as it passes from the small mixing chamber 172, through the apertures 326 of the diffuser 325, and into the load chamber 173. A diverter 155 is positioned above the RF load 300. A thin gap is present between the diverter 155 and the heatsink(s) 310 through which the coolant travels, thereby increasing the convective heat transfer and assisting the coolant reaching the output path 156 evenly from both heat sinks. Diverter 155 also adds insulation above the coolant (on the top of the coolant), thereby further reducing conductive loss upwards. In some embodiments, diverter 155 is comprised of a low thermal conductivity material, such as closed cell foam, or 3D printed with small air voids. The above helps to facilitate forced-convection, which almost completely transfers the RF energy to the coolant.

Diverter 155 also forms an output path 156 for the coolant to exit the load chamber 173 and through the turbulent mixer 150. The temperature of the coolant is measured immediately after exiting the turbulent mixer 150 using the outlet coolant temperature sensor 140. The measurement of the coolant temperature by the outlet coolant temperature sensor 140 is passed by the outlet coolant temperature sensor 140 to an external device, such as a microcontroller, via sensor leads extending from the coolant temperature sensor outlet pipe 141.

A distal end 142 of the coolant temperature sensor outlet pipe 141 has a conductive portion where outlet coolant temperature sensor 140 is located. Thus, outlet coolant temperature sensor 140 is positioned as close to the RF load 300 as possible. After the temperature of the coolant is measured by the outlet coolant temperature sensor, the coolant travels down the output path 156 formed by diverter 155 to the coolant outlet pipe 131 and exits the liquid-cooled termination 100 through the coolant outlet 130. The coolant outlet 130 and coolant outlet pipe 131 are constructed of a low thermal conductivity material, such as quartz, or another material with similar thermal properties as the outer conductor 215, to minimize conductive heat loss to the case 105.

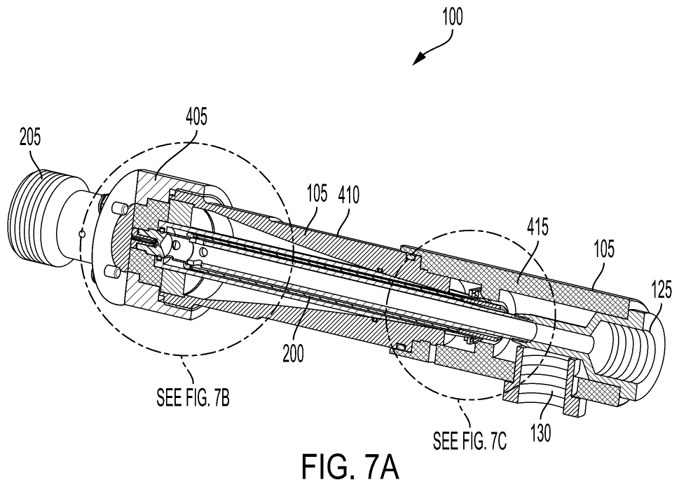

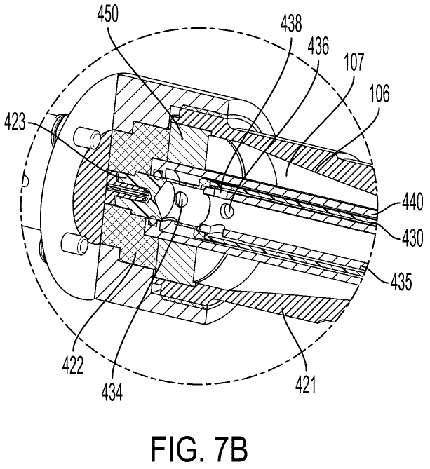

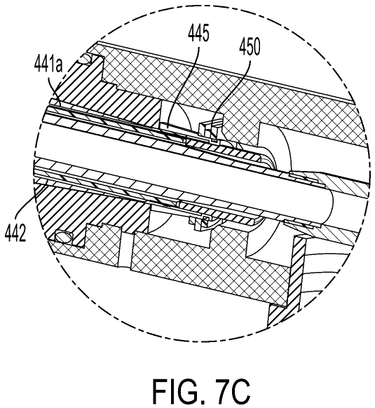

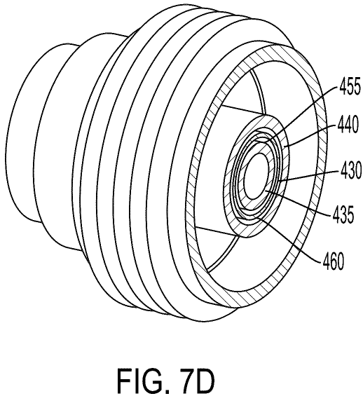

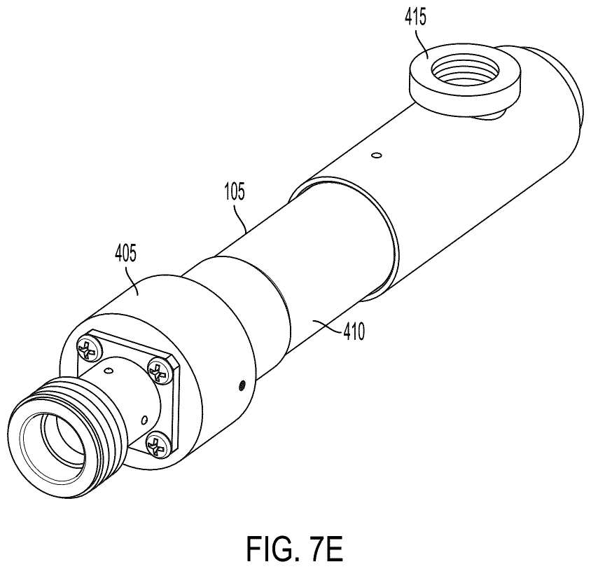

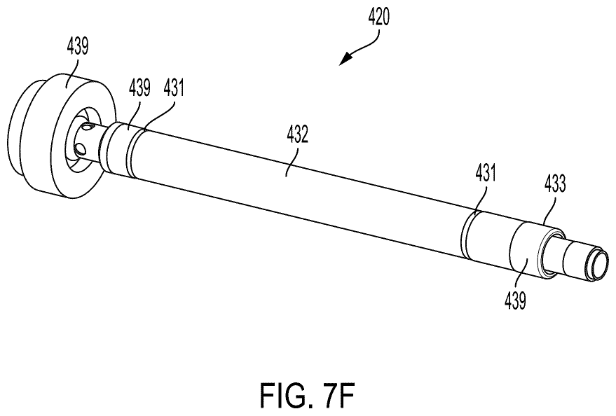

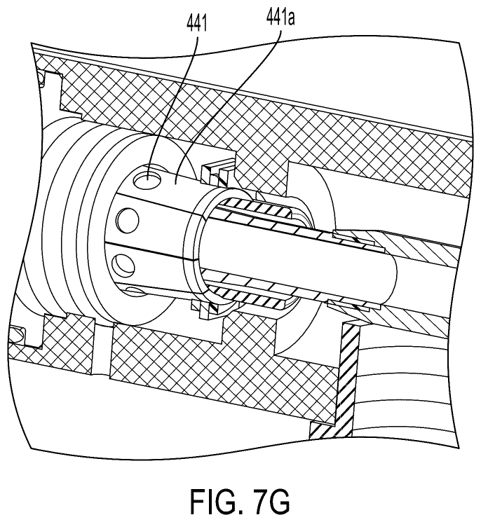

FIGS. 7A-G show an embodiment of liquid-cooled termination 100 which has a coaxial dual-flow load configuration. Liquid-cooled termination 100 has a case 105. The case 105 may also function as the outer conductor 215 of transmission line 200. The case 105 functions as an enclosure for the RF load 300 and a ground return path for the RF energy provided on the inner conductor 220. In some embodiments, the case 105 can be made from an electrically conductive metal, such as aluminum or stainless steel, or metal with an electrically conductive plating, such as silver plated brass. The case 105 has an input connector 205, inlet coolant temperature sensor 135, outlet coolant temperature sensor 140, coolant inlet 125, and coolant outlet 130. In an embodiment, case 105 is divided into multiple sections, such as an RF input section 405, a resistor assembly holder section 410, and a coolant section 415. These sections may be mechanically attachable, such as through threads. In other embodiments, these sections can be joined by welding or brazing. In an embodiment, the RF input section 405 and resistor assembly holder section 410 can be made from an electrically conductive metal, such as aluminum or stainless steel, or metal with an electrically conductive plating, such as silver plated brass. The coolant section 415 can be made from plastic or other non-conductive material, such as chlorinated polyvinyl chloride (CPVC).

Resistor assembly 420 is comprised of an inner conductor support 422 on a first end 421 and an inner conductor 430 that is supported by the inner conductor support 422. The inner conductor 430 is a tubular, ceramic substrate with a conductive coating 431 applied to the circumference of a portion of both ends of the inner conductor 430. A resistive coating 432 is also applied to the circumference of the inner conductor 430. The resistive coating 432 is located along the length of inner conductor 430 between the conductive coating 431 portions. The resistive coating 432 is in electrical contact with the conductive coating 431 located at each end of the inner conductor 430. The resistive coating 432 may be a thick-film sintered ink or CVD carbon film. Thereby, inner conductor 430 functions as the resistor 305 of the resistor assembly 420 of liquid-cooled termination 100. The conductively coated ends of the inner conductor 430 have interface structures 439 that provide mechanical support, indexing, and electrical continuity to the remainder of the case 105 and liquid-cooled termination 100.

The inner conductor 430 of the resistor assembly 420 is electrically connected to the inner conductor 208 of the RF input connector 205 at the first end 439 of the resistor assembly 420. A resistor holder 423 includes parts that electrically connect the resistor inner conductor 430 to the RF input connector 205. The resistor holder 423 may include an inner connector sleeve connected to a resistor spring fitting that makes an electrical connection between the inner conductor 430 of the resistor assembly 420 and the inner conductor of the RF input connector 205. An inner conductor support 450 may also be present that is an electrically non-conductive material that provides mechanical support and stabilization of the inner conductor 430 and rest of the resistor assembly 420. It also helps to match and adjust the impedance along the transmission line 200 of the liquid-cooled termination. The resistor assembly 420 has an inner flow tube 435 located coaxially inside of the inner conductor 430. The inner flow tube 435 at a second end 433 of the resistor assembly 420 interfaces with and receives coolant from the coolant inlet 125. The coolant travels along an interior 439a of the inner flow tube 435. The inner flow tube 435 and the inner conductor 430 each have a set of flow path apertures. The first set of apertures are inner flow path apertures 436 located on the inner flow tube 435 and arranged in an array around the circumference of the inner flow tube 438. The second set of apertures are outer flow path apertures 434 are arranged in an array around the circumference 430a of the inner conductor 430. The outer flow path apertures 434 are located closer to the first end 439 of the resistor assembly than the inner flow path apertures 436. In an embodiment, each of the inner flow path apertures 436 are arranged in a single array row and outer flow path apertures 434 are arranged in a single array row. In some embodiments, the array rows of inner flow path apertures 436 and outer flow path apertures 434 are arranged next to each other.

The resistor assembly 420 also has an outer flow tube 440 that is coaxially located around the inner conductor 430. The outer flow tube 440 is a non-conductive tube placed, concentrically, around the inner conductor 430. The portion of the exterior 441a of the outer flow tube 440 located at the second end 433 of the resistor assembly 420 has a taper 442 that continues and corresponds with the tapered interior 106 of the case 105.

The resistor assembly 420 is supported on a second end 433 by a compression rings to the case 105, which maintains the resistor assembly 420 in coaxial alignment with the case 105 and laterally holds the resistor assembly 420 in place. The rear resistor contact 445 makes electrical contact with the housing 105 to make electrical continuity with the inner conductor 430, thereby providing a return path back to the RF input connector 205 through the case 105. The components of the resistor assembly 420 and other components of the liquid-cooled termination 100 are chosen such that the characteristic impedance of the final transmission line construction of the liquid cooled termination are as close to 50 ohms as possible. In addition, the tapered interior 106 of the case 105 creates a conical or tapered shape that ensures proper impedance matching of the device at high frequencies. The dimensions of the outer flow tube 440 are matched to provide proper impedance in the transmission line 300. The outer flow tube 440 is also tapered to match that of the tapered interior 106 of the case 105.

In operation, RF power is applied to the input connector, which heats up the resistive coating on the inner conductor 430. Coolant is then provided to the coolant inlet 125 and passes down the inner flow tube 435. After the coolant travels the length of the inner flow tube 435, it exits through the inner flow path apertures 436. A portion of this coolant then travels down an inner flow path between an exterior of the inner flow tube 435 and an interior of the inner conductor 430. Heat is transferred from the resistive coating of the inner conductor 430 to the fluid travelling down the inner flow path annular passage 455.

Further, another portion of the coolant travelling through the inner flow path apertures 436 then travels through the outer flow path apertures to the outer flow path between an exterior of the inner conductor 430 and the interior of the outer flow tube 440. Heat is transferred from the resistive coating of the inner conductor 430 to the fluid travelling down the outer flow path annular passage 460.

The coolant then exits the outer flow path annular passage 460 through outer flow tube apertures 441 once it reaches coolant section 415. The coolant exits the inner flow path annular passage 455 once it reaches the second end 433 of the inner conductor 430 in coolant section 415. The coolant then exits the coolant section through the coolant outlet 130. In some embodiments a turbulent mixer 150 is present and the coolant passes through the turbulent mixer immediately prior to exiting through the coolant outlet 130.

In some embodiment, an interior of the resistor assembly 430 is cooled to a lesser degree to minimize thermal stress on the ceramic substrate. Because the coolant and outer flow tube surround the resistive heating film, parasitic heat loss is minimized by the insulative properties of the flow tube.

Some embodiments of liquid-cooled termination 100 may have inlet coolant temperature sensor 135 and the outlet coolant temperature sensor 140 integrated into the case 105. In other embodiments, inlet coolant temperature sensor 135 and the outlet coolant temperature sensor 140 may be located external to the case 105 and measurements are taken immediately prior to entering the coolant inlet 125 and exiting the coolant outlet 130.

As can be seen, all of the coolant remains inside the outer flow tube 440 when the coolant is flowing through the resistor assembly 430 in the resistor assembly holder section 410. The coolant only enters and exits the resistor assembly 430 at the coolant section 415. This permits there to be an air gap 107 between the case 105 and the outer flow tube 440 at the RF input section 405 and resistor assembly holder section 410, which provides insulation and helps to minimize heat transfer outside of the case 105 of the liquid cooled termination.

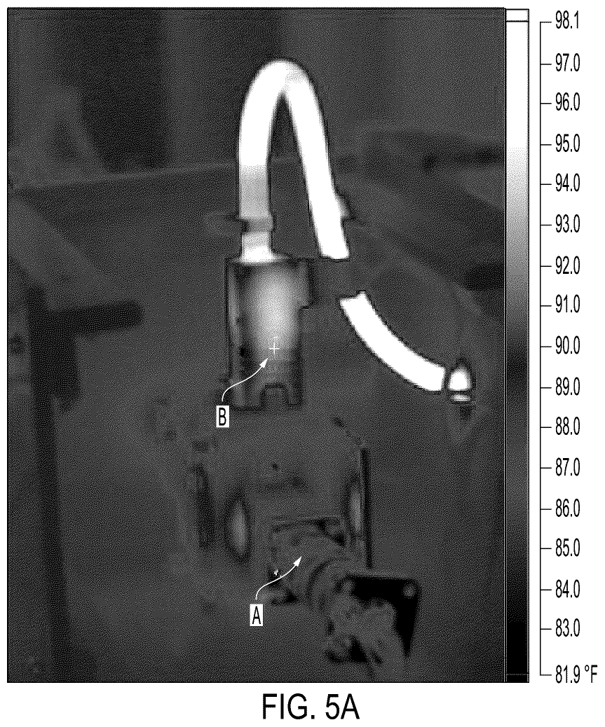

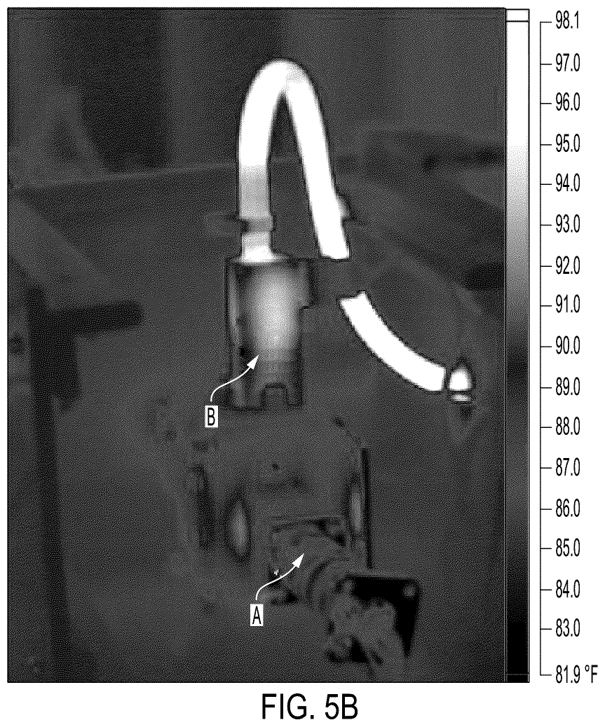

FIGS. 5A-B show a thermal images of a liquid-cooled termination 100 in use with a calorimeter in accordance with an embodiment of this invention. 100 W of power is being applied to the RF load 300. Point B has a temperature of 91° F., and Point A has been denoted to show that there is no noticeable heating of the RF input connector 205. More specifically, the hose connected to the coolant outlet of the liquid-cooled termination 100 has a temperature of 91° F., while at the same time, the input connector 205 is at room temperature. In prior art designs, heat loss through the input connector 205 has been a problem, which results in an error in the measured power. The features of the embodiments of the liquid-cooled termination 100 discussed herein substantially reduce the heat loss from liquid-cooled termination 100, which results in a decreased error in the measured power.

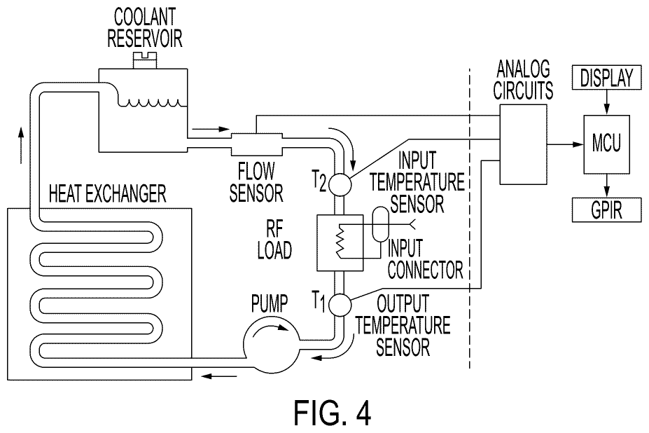

FIG. 4 shows a closed loop calorimeter 900 having a liquid-cooled termination 100 in accordance with an embodiment of this invention.

### Statements of the Invention

### Primary Statements

A liquid-cooled, termination used for calorimetric power measurement that is constructed to promote high thermal efficiency such that the overall power measurement accuracy is better than 0.25%
A liquid-cooled, termination used for calorimetric power measurement that is constructed to provide for a thermal settling time such that the accuracy noted in claim #1 can be obtained in under 60 seconds.
A liquid-cooled, termination used for calorimetric power measurement that is constructed such that reflected energy is minimized providing the accuracy stated in claim #1.
A liquid-cooled, termination used for calorimetric power measurement that is constructed such that the mixing of heated coolant occurs which provides for accurate temperature measurement at the output of the embodiment providing the accuracy stated in claim #1.
A liquid-cooled, termination used for calorimetric power measurement that uses one or more techniques outlined in the above claims in any combination.

### Additional Statements

Construction method of transmission line, when connected between a coaxial RF interface and an RF transition or RF load, minimizes conductive heat loss from the planar load,
Construction of a transmission line structure with an inner conductor comprised of a small cross-section, electrically conductive, thin-walled tube
Construction of a transmission line structure with an outer conductor comprised of a thermally insulating tube that is plated with electrically conductive material on the external surface.
Construction of a transmission line structure with an outer conductor comprised of a glass, quartz, sapphire or ceramic tube that is plated with electrically conductive material on the external surface.
Placing the resistive film in intimate contact with the coolant enabling direct convection heat transfer to the coolant
Placing the resistive film that is applied using a thick-film ink process to the substrate in intimate contact with the coolant enabling direct convection heat transfer to the coolant
Placing the resistive film that is applied using a chemical vapor deposition process to the substrate in intimate contact with the coolant enabling direct convection heat transfer to the coolant
Smaller packaging geometry enabling high-frequency use and lowers the total surface area for parasitic, convective heat loss.
Using a planar load approach, smaller geometries are readily achieved enabling high-frequency use. The small size also minimizes packaging which in-turn lowers the total surface area for parasitic, convective heat loss.
Use of an integrated heat sink attached to the load assembly provides larger surface area for convective heat transfer, removal of energy & transfer to the fluid.
Isolation of the load from conductive heat loss paths using minimal mounting to structures exposed to ambient air.
Placing the input temperature sensor as close to the planar load as possible to accurately measure the initial coolant temperature and offset error due to residual pre-heating of the incoming fluid or due to outside influences.
Use of a turbulent mixer in between the planar load and the output temperature measurement to minimize gradients and fluctuations resulting from the short distance from the heat source and temperature rise measurement mechanism.
Constructing the conduits for temperature sensors and signal wires from an insulating tube to minimize conductive heat loss to the external environment.
Constructing the fluid conduits to and from the planar load assembly out of insulating tubes to minimize conductive heat loss to the external environment.
Enclosing the load assembly in a separate fluid chamber which insolates the heat source from conductive heat loss to external environment using air or a closed-cell insulating material
Using a diffuser between the inlet and load to balance coolant flow between areas of the planar load to ensure convection coefficients are matched to areas of higher heat flow. This ensures the temperature distribution on the load/heatsink is even for maximum convective heat transfer.
Using a diverter or insulator surrounding the load/heatsink assembly to ensure the coolant maintains direct contact with the heat source and directs the heated coolant to the outlet reducing contact with conductive paths.
Isolating the heat source and measurement sensors from fluctuations from the external environment.
Commercial off-the shelf (COTS) planar load assembly can easily be integrated into the embodiments.
Having a tubular, coaxial structure to minimize return loss (i.e. reflected energy).
An outer flow tube to direct coolant directly over the resistive heating structure to maximize energy transfer to the coolant.
An inner flow tube inserted coaxially inside the supporting substrate to direct coolant in the inside of the supporting substrate to minimize thermal stress gradients.
An outer conductor that is constructed with a taper to provide proper impedance matching & low reflected power.
An outer flow tube that is inserted coaxially over the resistive heating film and is dimensionally matched to the impedance of the transmission line
An outer flow tube that is tapered to provide proper impedance matching & low reflected power.
Placing a resistive film on an insulating, ceramic, tubular substrate
Placing a resistive film on an insulating, planar substrate
Use of a heat-sink constructed using a folded-fin topology
Use of a heat-spreader such that the coolant progresses both through the fins and over the base and attached load
A heat-sink is constructed of a thin herringbone folded fin structure with an integrated heat spreader
A heat sink that is soldered to both sides parallel to the coolant flow path.
Using materials and construction that allows for the embodiments to be compatible with a variety of coolant other than pure water.

While this invention has been described in conjunction with the specific embodiments described above, it is evident that many alternatives, combinations, modifications and variations are apparent to those skilled in the art. Accordingly, the preferred embodiments of this invention, as set forth above are intended to be illustrative only, and not in a limiting sense. Various changes can be made without departing from the spirit and scope of this invention. Combinations of the above embodiments and other embodiments will be apparent to those of skill in the art upon studying the above description and are intended to be embraced therein. Therefore, the scope of the present invention is defined by the appended claims, and all devices, processes, and methods that come within the meaning of the claims, either literally or by equivalence, are intended to be embraced therein.

1. A liquid-cooled termination for calorimic RF power measurement comprising:
an RF transmission line, a coolant flowpath having a coolant input and a coolant output, and an RF load;
said RF transmission line being electrical communication with said RF load having a resistor and a heat sink;
said RF load is in said coolant flowpath, such that said heat generated by said RF power being applied to said RF load through said RF transmission line is convected to said coolant while said coolant flows past said RF load.

2. The liquid-cooled termination of claim 1, wherein said liquid cooled termination further comprises a turbulent mixer located along said coolant flowpath between the RF load and the coolant output.

3. A calorimeter having a liquid-cooled termination for RF power measurement comprising:
an RF transmission line, a coolant flowpath having a coolant input and a coolant output, and an RF load;
said RF transmission line being electrical communication with said RF load having a resistor and a heat sink;
said RF load is in said coolant flowpath, such that said heat generated by said RF power being applied to said RF load through said RF transmission line is convected to said coolant while said coolant flows past said RF load.

4. The liquid-cooled termination of claim 3, wherein said liquid cooled termination further comprises a turbulent mixer located along said coolant flowpath between the RF load and the coolant output.
